(19) United States
(12) Patent Application Publication
(10) Pub. No.: US 2007/0090849 A1
(43) Pub. Date: Apr. 26, 2007

(54) Method and apparatus for a DUT contactor

(76) Inventor: Romi Mayder, San Jose, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/257,143

(22) Filed: Oct. 24, 2005

(51) Int. Cl. G01R 31/02

(52) U.S. Cl. 324/763

(57) ABSTRACT

A DUT contactor integrated into a DUT or probe board is presented. The DUT contactor integrated into a DUT/probe board may comprise a raised metallization contact layer on one surface of a multi-layer printed circuit board.

### BACKGROUND

Central to the design of a high end automated test system is a contactor. A contactor essentially acts as the final link connecting the test system to the device under test. Traditionally, the automated test equipment (ATE) industry has used device under test (DUT) or probe boards to route signals from the ATE system to the location of the DUT pins. A contactor would then be placed on top of the DUT or probe board. The DUT would then be inserted into the contactor, which would enable the balls or leads of the DUT to make electrical contact to the DUT or probe board. There is one contact between the DUT ball and the contactor and then one contact between the contactor and the DUT or probe board. Thus, each pin of the DUT will require two contacts to make electrical contact to the DUT or probe board. Also, the electrical length of a typical contactor adds unwanted inductance to the signal path between the DUT and the ATE system.

Different contactors are each specifically designed to meet the requirements of each specific DUT to be tested. Generally, more than one contactor may be mated to a particular DUT or probe board, each being switched out to accommodate a particular DUT to be tested. While there are a number of contactor styles, most contactors generally use spring pins, elastomer, cantilever or microstrip lead frame as contacts. Thus, contactors heretofore have generally been expensive, have long lead times from design to delivery and are prone to contact failures. Therefore, there is a need to reduce some of the limitations of prior DUT contactors in the ATE industry.

### BRIEF DESCRIPTION OF THE DRAWINGS

An understanding of the present teachings can be gained from the following detailed description, taken in conjunction with the accompanying drawings of which:

FIG. 1 shows a perspective view of a test head with a probe or DUT board and a contactor thereon.

FIG. 2 shows a side cut-away view of a spring pin contactor with a DUT and DUT/probe board.

FIG. 3 shows a side cut-away view of a cantilever contactor with a DUT and DUT/probe board.

FIG. 4 shows a side cut-away view of a DUT and a combination contactor/DUT board.

### DETAILED DESCRIPTION

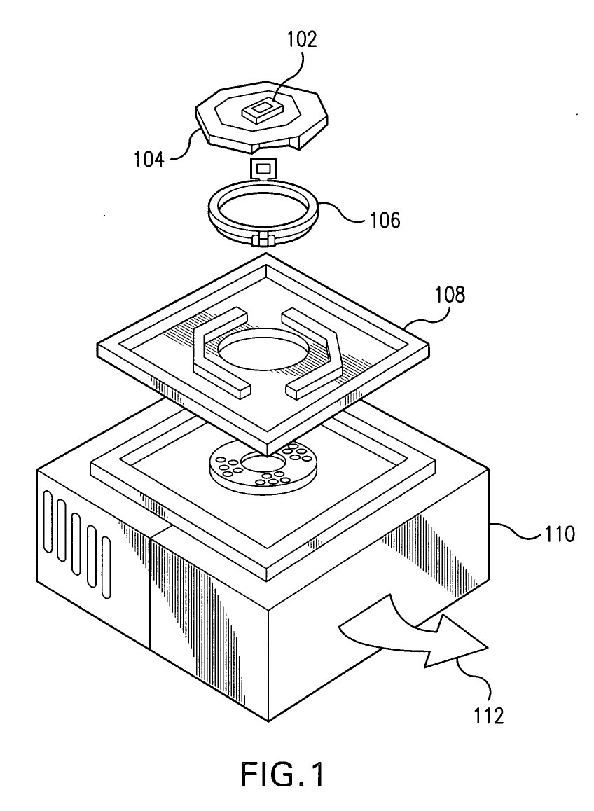

FIG. 1 shows a typical contactor 102 mounted on a probe or DUT board 104. The probe or DUT board 104 may be secured to a load board 108 with a connecting collar 106. The load board 104 is mounted to a test head 110. The test head 110 communicates with a test system (not shown) be a cable assembly 112 or other data transmission means. The contactor 102 enables the balls or leads of a DUT (not shown) to make electrical contact to the DUT or probe board 104.

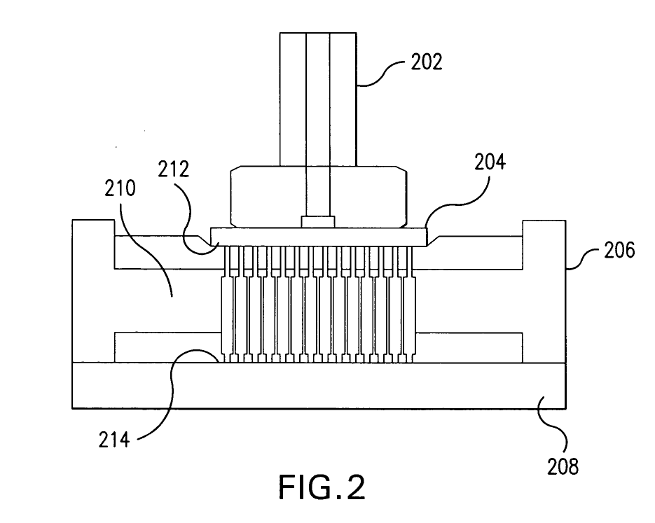

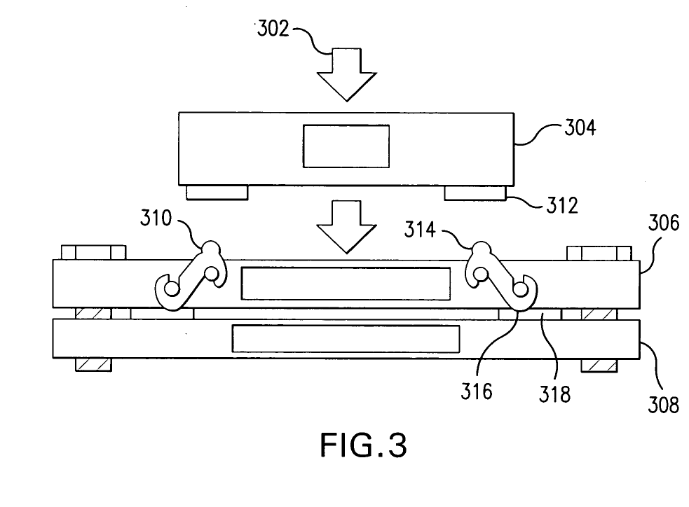

FIG. 2 shows a typical plunger or clamp 202 securing a DUT 204 to a contactor 206 with spring pins 210 on a DUT or probe board 208. FIG. 2 illustrates a contact 212 between the DUT 204 and the contactor 206 at one end of the spring pins 210 and a second contact 214 between the second end of the spring pins 210 and the probe or DUT board 208. FIG. 3 shows a typical plunger or clamp 302 securing a DUT 304 to a contactor 306 with cantilever contacts 310 on a DUT or probe board 308. FIG. 3 illustrates a first contact between balls or leads 312 of the DUT 304 and a first end 314 of the cantilevers 310 and a second contact between the second end 316 of the cantilevers 310 and a contact pad 318 on the DUT or probe board 308.

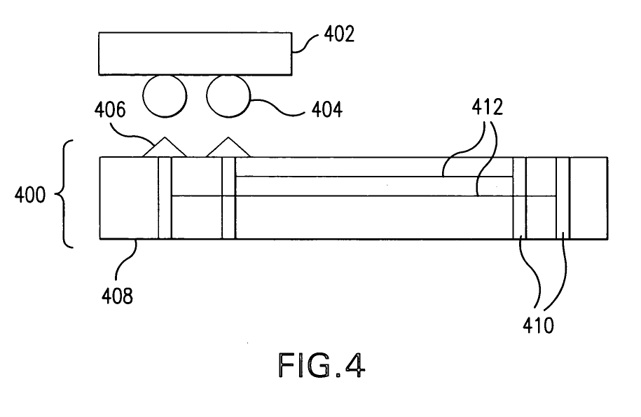

FIG. 4 shows a DUT 402 with contact pads 404, such as leads or solder balls. Also shown in FIG. 4, is an integrated contactor and DUT or probe board 400 with multi-layers 412, vias 408 for carrying signals 410 to and from an automated test system (ATE) (not shown), and raised metallization contact pads 406. Contact pads 406 are aligned with the contact balls 404 on the DUT. Thus, when the DUT 402 is brought into contact with the integrated contactor/DUT board 400 by a plunger or clamp (not shown), sufficient contact between DUT balls 404 and contactor contact pads 406 may be realized.

The integrated contactor/DUT board 400 may include multi-layer 412 printed circuit board with 200 μin Nickel and 50 μin gold on the outer layers. Next, pads may be masked underneath and corresponding with DUT balls 404 by with a lithography process or other similar process. Next the metallization may be chemically under etched to partially free the metal from the PCB laminate. The metal will then float away from the surface of the PCB due to the tensile load of the metal. Alternatively, a mechanical post-processing step may be utilized to ensure sufficient tensile load of the outer metallization layers of the PCB. For example, a mechanical cylinder may be inserted through the via hole from the back-side of the PCB to impart a load on the etched finger leafs to create a permanent deformation that would lift the springs to an appropriate height. Also another possible alternative would be to use a wire bond machine to lift the etched finger leafs.

The metal may be BeCu, Phosphor Bronze or other metal or composites of similar characteristics to accommodate the desired spring force for the contact pads 406. The spring force may be adjusted by the size of the masking area on the PCB. The fabrication process controls and the etch rate of the metal may be controlled to ensure the raised metal contact pads 406 are of uniform height to ensure contact with DUT balls 404 when compressed by a plunger or clamp during the testing process. The BeCu, Phosphor Bronze or other metallization may be clad to the outer layers of the PCB with standard foil process technology using heat and compression forces or other known techniques.

The integrated contactor and DUT board 400 can eliminate one contact per DUT pin, effectively removing the electrical length of the contactor, which substantially improves the inductance in the signal path. The cost of the contactor will be replaced by the minimal cost of the raising up of the metal contact pads 406 on the PCB underneath the DUT board. This will probably be relatively cheap, as a lithographic or other similar process, especially when compared to the price and design complexity of typical contactors.

Other features may be added to the DUT board, such as alignment features with the same or similar processes as are used to create the contactor contact pads 406.

1. A contactor integrated DUT board comprising:
a multi-layer printed circuit board having raised contactor pads on an outer layer of the multi-layer printed circuit board which are directly connectable to solder balls of a device under test (DUT) which is mountable thereon, and vias which are electrically coupled to the raised contactor pads.

2. The DUT contactor integrated DUT board according to claim 1, wherein the raised contactor pads are BECu.

3. The DUT contactor integrated DUT board according to claim 1, wherein the raised contactor pads are Phosphor Bronze.

4. A method for manufacturing a DUT contactor integrated DUT board comprising the following steps:
forming a multi-layer printed circuit board;
forming vias in the multi-layer printed circuit board;
masking pads to correspond with contact balls on a DUT on an out layer of the multi-layer printed circuit board; and
etching the metallization to form contactor pads on the multi-layer printed circuit board.

5. The contactor integrated DUT board according to claim 1, wherein:
the DUT is mounted on the multi-layer printed circuit board such that the solder balls of the DUT are directly connected to the raised contactor pads.

6. The contactor integrated DUT board according to claim 1, wherein:
the vias of the multi-layer printed circuit board are connected to signal channels of a DUT tester.
